(19) United States
(12) Patent Application Publication
(10) Pub. No.: US 2010/0102841 A1
(43) Pub. Date: Apr. 29, 2010

(54) DEVICE, METHOD AND PROBE FOR INSPECTING SUBSTRATE

(75) Inventors: Hideya Kawada, Ogaki-shi (JP); Koji Takahashi, Ogaki-shi (JP)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(73) Assignee: IBIDEN CO., LTD., Ogaki-shi (JP)

(21) Appl. No.: 12/605,859

(22) Filed: Oct. 26, 2009

Related U.S. Application Data
(60) Provisional application No. 61/108,925, filed on Oct. 28, 2008.

(51) Int. Cl. G01R 31/02; G01R 1/06

(52) U.S. Cl. 324/757

(57) ABSTRACT

A device for inspecting a substrate, including a probe and a support member configured to hold the probe is disclosed. The probe comprises a compression spring and includes a conductive material to measure an electric property of a substrate under inspection.

### CROSS-REFERENCE TO RELATED APPLICATIONS

This patent application claims the benefit of U.S. Provisional Patent Application No. 61/108,925, filed Oct. 28, 2008, which is incorporated by reference.

### BACKGROUND OF THE INVENTION

A printed wiring board has an IC chip and wiring patterns connected to the IC chip. The electrical signals are transmitted to the IC chip through the wiring patterns. The resistance of the wiring patters affects the efficiency in transmitting the electrical signals or supply power to the IC chip. As such, the resistance of the wiring patterns is measured at the time of inspecting the quality of a substrate. One method for measuring the resistance is a four-terminal measurement that uses needle pins and tests the continuity of a wiring pattern. The method is briefly explained with reference to FIGS. 7A and 7B.

FIGS. 7A and 7B are schematic illustrations of probes (needle pins) 220, 230 of a conventional inspection device, and a substrate 90 having a bump 92. To measure the resistance of wiring patterns formed in the substrate 90, two needle pins 220, 230 are brought into contact with the bump 92 having a semicircular shape. FIG. 7A shows the needle pins 220, 230 making a contact with the bump 92 at their tip portions. However, it is believed that the needle pins 220, 230 do not always make a secure contact with the bump 92. For example, as shown in FIG. 7B, the tip portion of the needle pin 220 may fail to make a contact with the bump 92. It is believed that this problem tends to occur when the two needle pins 220, 230 are made of a flexible wire, and the bump 92 has a semicircular shape. In the four-terminal measurement, two fine needle pins are used to make a contact with one bump, and thus the poor contact as illustrated in FIG. 7B may frequently occur.

As the elements of printed wiring boards become finer, the bumps at inspection points are expected to become even smaller. When the bumps become smaller, the phenomenon shown in FIG. 7B may occur more frequently. Thus, a device that allows a more reliable and precise measurement is desired.

### BRIEF SUMMARY OF THE INVENTION

The invention provides a probe for inspecting a substrate. In one embodiment, the probe includes a probe body comprising a compression spring and including a conductive material to measure an electric property of a substrate under inspection.

The invention also provides a device for inspecting a substrate. According to one embodiment, the device includes a probe and a support member configured to hold the probe. The probe comprises a compression spring and includes a conductive material to measure an electric property of a substrate under inspection.

The invention further provides a method for inspecting a substrate. In a method according to one embodiment of the present invention, probes are provided, a contact between the probes and an inspection point of a substrate is made, an electric current is supplied to the inspection point through one of the probes, and a voltage is measured by another probe. The probes each comprise a compression spring and include a conductive material to measure an electric property of a substrate under inspection.

### BRIEF DESCRIPTION OF THE SEVERAL VIEWS OF THE DRAWING(S)

FIG. 1 is a schematic side view of an inspection device according to a First Embodiment of the present invention, and a substrate to be inspected.

FIG. 2A is a magnified side view of the circle “C” area indicated by the broken line in FIG. 1. FIG. 2B is a cross-sectional view of FIG. 2A. FIG. 2C is a view from the bottom of a probe shown in FIGS. 2A and 2B.

FIGS. 3A-3C are side views of probes provided in the inspection device according to the First Embodiment, showing the probes coming into contact with a bump formed on the substrate under inspection.

FIG. 4A is a side view of an inspection device according to a Second Embodiment of the present invention, and a substrate to be inspected. FIG. 4B is a magnified, cross-sectional view of the circle “C” area indicated by the broken line in FIG. 4A.

FIGS. 5A-5C are side views of probes of the inspection device according to the Second Embodiment, showing the probes coming into contact with a bump formed on the substrate under inspection.

FIG. 6 is a side view of an inspection device according to a Third Embodiment of the present invention, and a substrate to be inspected.

FIGS. 7A and 7B are schematic illustrations of probes of a conventional inspection device. FIG. 7A shows tips of the probes making a contact with a bump formed on a substrate, and FIG. 7B shows the tip of a probe out of contact with the bump.

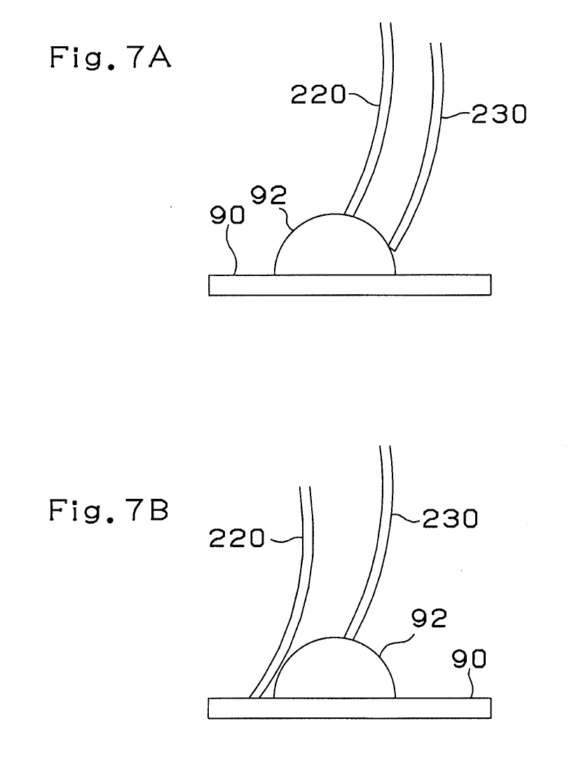

### DETAILED DESCRIPTION OF THE INVENTION

### First Embodiment

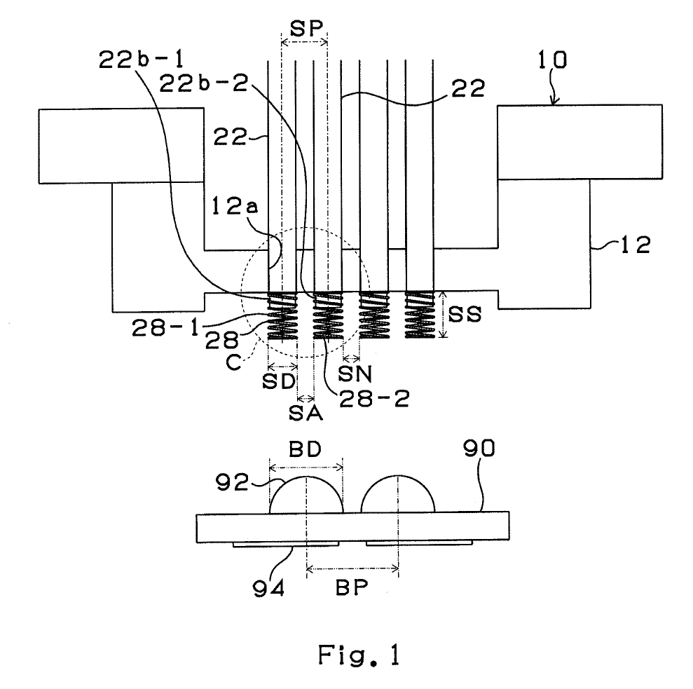

A device, method and probe for inspecting a substrate according to the First Embodiment of the present invention are described with reference to FIGS. 1-3C.

FIG. 1 is a schematic side view of an inspection device 10 according to the First Embodiment and a substrate 90 to be inspected. The inspection device 10 can be used to measure an electric property of the substrate 90. In the illustrated embodiment, the substrate 90 has bumps (electrodes; inspection points) 92 formed on one surface and pads 94 on the opposite surface. The bumps 92 and pads 94 are connected through wiring patterns (not shown) formed in the substrate 90. The inspection device 10 can be used to measure resistance of the wiring patterns by employing a four-terminal method. The inspection device 10 is part of an inspection system (not shown) including measuring apparatus for measuring electrical features of the substrate 90. The inspection device 10 is linked to the measuring apparatus in the inspection system through connection lines 22.

The inspection device 10 includes an inspection probe (hereinafter, “probe”) 28 and a support member 12 for holding the probe 28. The probe 28 comprises a compression spring and includes a conductive material to measure an electric property of the substrate 90. In one example, the probe 28 electrically connected to the connection line 22 is brought into contact with the bump 92 having a substantially semicircular shape to conduct the measurement. The support member 12 has a through-hole (12a) to receive the connection line 22. The connection line 22 has a conductive part exposed at an electrode section (22b-1, 22b-2) where the probe 28 is electrically connected. The electrode section (22b-1, 22b-2) protrudes from the support member 12 toward the substrate 90.

In a four-terminal method, four probes 28 are used for the measurement. The probes 28 comprise a current supply probe (28-1) and a voltage measuring probe (28-2). The probes 28 are positioned in the inspection device 10 so that one pair of the current supply probe (28-1) and the voltage measuring probe (28-2) make contact with the same bump 92. Another pair of the current supply probe (28-1) and the voltage measuring probe (28-2) are brought into contact with the adjacent bump 92. In measuring an electric property of the substrate 90, an electric current is supplied to one of the bumps 92 through the current supply probe (28-1), and a voltage is measured by the voltage measuring probe (28-2).

In order to make contact with the bumps 92, the probes 28 are moved toward the bumps 92. This movement (stroke) is vertical to the substrate 90. For the probes 28 to move as a stroke in a direction vertical to the substrate 90, the through-holes (12a) are formed substantially vertically with respect to the substrate 90. During the measurement, the front end portion of the probe 28 is brought into contact with the inclined surface of the substantially semicircular bump 92, and the probe 28 is pressed further against the bump 92. The probes 28 are held by the support member 12 so that a pair of the probes 28 pressed against the bump 92 are slightly warped away from each other in an outward direction along the periphery of the bump 92.

The probe 28 can have a total length (SS) of, for example, about 100 μm to about 600 μm, and an external diameter (SD) of, for example, about 20 μm to about 100 μm. The probes 28 can be provided at a pitch (SP) of, for example, about 30 μm to about 140 μm. The distance (SA) between the current supply probe (28-1) and voltage measuring probe (28-2) can be, for example, about 5 μm to about 30 μm. The minimum distance (SN) between the probe used for measuring one bump and the probe used for another bump next to the bump can be, for example, about 5 μm to about 40 μm. The probe 28 can comprise a compression spring. Examples of the compression spring include a coil spring and a leaf spring, and a coil spring is preferable. The stroke of the probe 28 can be, for example, about 50 μm to about 500 μm.

Substrates 90 may have bumps 92 of any suitable size. For example, bumps 92 may have a diameter (BD) of, for example, about 50 μm to about 120 μm and may be formed with a pitch (BP) of, for example, about 110 μm to about 180 μm.

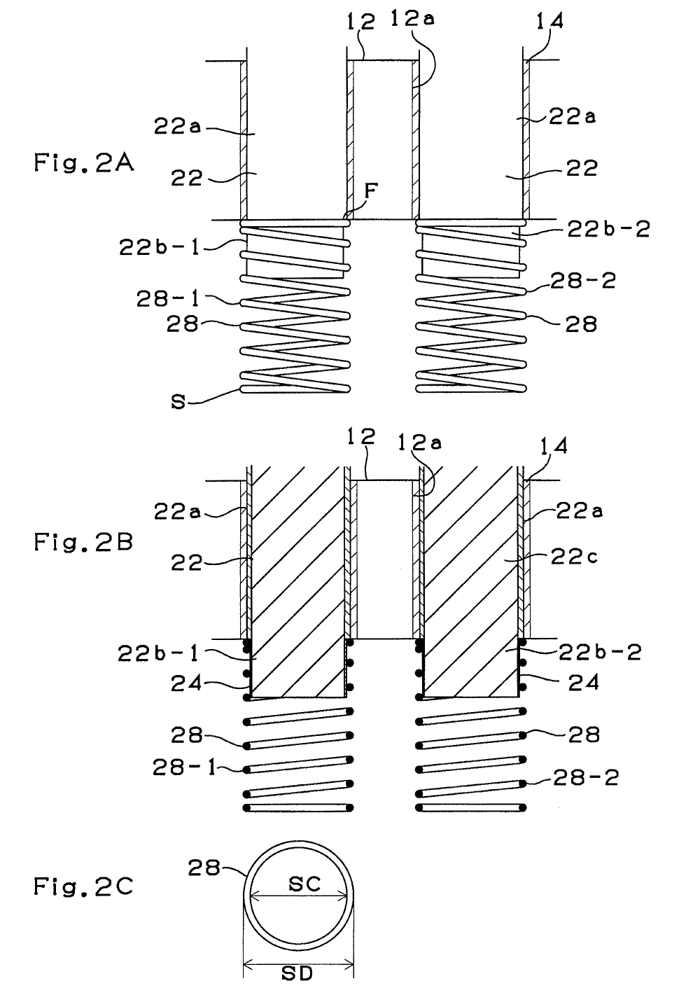

FIG. 2C is a schematic illustration of the bottom part of the probe 28. The probe 28 can have an external diameter (SD) of, for example, about 20 μm to about 100 μm, and an internal diameter (SC) of, for example, about 10 μm to about 80 μm. The external diameter (SD) is preferably about ½ to about ¼ of the diameter (BD) of the bump 92 to allow a secure contact between the probe 28 and the bump 92 without causing the probes 28 to touch one another. A spring having an external diameter (SD) substantially smaller than ¼ of the diameter (BD) may be harder to manufacture with a high precision.

In one example, the probe 28 comprises a wire, for example, piano wire (high carbon steel wire) with a wire diameter of, for example, about 5 μm to about 20 μm. The wire preferably has a diameter of about 1/22 to about ¼ of the external diameter (SD) of the probe 28. The probe 28 preferably comprises such a small diameter spring with superior flexibility. If the wire diameter is substantially smaller than 1/22 of the external diameter (SD), durability may become lower.

The probe 28 preferably comprises a spring having a stroke range of about 50 μm to about 500 μm. The stroke within the range allows a proper measurement even if the bumps 92 have varying heights, or a substrate to be inspected has an uneven surface. If a spring has a stroke that substantially exceeds 500 μm, the spring may be largely warped away from the vertical direction when being pressed against the bump 92. In contrast, when the probe 28 comprises a spring having a stroke within the preferred range, the probe 28 can expand and contract in a more vertical direction when being pressed against or separated from the bump 92. Thus, the probe 28 can make an appropriate contact with the bump 92.

When the probe 28 is pressed against the bump 92, the probe 28 receives a load of, for example, about 0.2 gf to about 6 gf. Preferably, a load of about 0.5 gf to about 5 gf is applied. Such a load allows an accurate measurement of the electrical features of a substrate for inspection, while increasing manufacturing productivity. This is because the mark formed on a bump when the spring touches the bump is reduced. Also, the load provides a proper contact pressure between the spring and the bump, and thus the contact resistance between the spring and the bump is lowered.

The probe 28 preferably comprises a spring having a pitch of ½ or less of the average diameter of the spring. The average diameter of a spring is defined as (SD+SC)/2, that is, a half of the sum of the external diameter (SD) and internal diameter (SC) of the spring. When the probe 28 comprises a coil spring, the total length (SS) of the spring divided by the pitch gives the number of coils.

It is preferable that the probe 28 comprises a spring that has a closed-loop bottom portion and does not have a loose end (see FIG. 2C). Such a spring is effective in avoiding the probes from becoming entangled or in improving the contact between the spring and the bump.

FIG. 2A is a magnified view of the portion indicated by the circle “C” in FIG. 1. FIG. 2B is a cross-sectional view of FIG. 2A. Part of the connection line 22 is placed in the through-hole (12a) of the support member 12. The connection line 22 comprises a conductive part (22c) and an insulative film (22a) that coats the conductive part (22c). For example, the connection line 22 can comprise copper wire and enamel film coating the copper wire. Instead of an enamel coating, a Teflon coating may be used, for example. The connection line 22 is fixed to the inner wall of the through-hole (12a) using an adhesive agent 14 such as an epoxy-type adhesive agent. The diameter of the connection line 22 can be, for example, about 10 μm to about 100 μm. The external diameter of the conductive part (22c) (such as copper wire) can be, for example, about 5 μm to about 80 μm. The length of the connection line 22 is not particularly limited, but the total length of the connection line 22 can be, for example, about 100 mm to about 1,000 mm.

As shown in FIGS. 2A and 2B, the electrode sections (22b-1, 22b-2) are placed in the probes (28-1, 28-2) comprising compression springs. The probe 28 has a front end portion (S) that touches the bump 92 of the substrate 90 and a rear end portion (F) opposite the front end portion (S). The electrode sections (22b-1, 22b-2) are provided in the rear end portion (F) of the probe 28. By providing the electrode sections (22b-1, 22b-2) in the rear end portion (F), the probe 28 and the electrode section (22b-1, 22b-2) are electrically connected to each other. The entire structure, from the front end portion (S) to the rear end portion (F) that is connected to the electrode section (22b-1, 22b-2), is preferably a compression spring. The compression spring is preferably a coil spring.

FIG. 2B is a cross-sectional view of FIG. 2A. The connection line 22 comprises a conductive part (22c) such as a conductive wire comprising copper, and the insulative film (22a) which coats the conductive part (22c). The probe 28 is connected to the front end portion (electrode section (22b-1, 22b-2)) of the connection line 22 where the insulative film is removed. To enhance the connection between the probe (28-1, 28-2) and the electrode section (22b-1, 22b-2) inserted in the probe (28-1, 28-2), the probe (28-1, 28-2) and the electrode section (22b-1, 22b-2) are connected using a conductive material 24 such as solder. Instead of solder, the electrode section and the spring may be fixed to each other using, for example, conductive paste or conductive adhesive paste. Also, the probe 28 may be caulked to the conductive part (22c) such as copper wire.

The probe 28 can comprise a compression spring comprising, for example, high carbon steel, stainless steel, beryllium copper, tungsten, or nickel. The probe 28 comprising a compression spring comprising such a material is superior in both elasticity and durability, and thus the probe 28 can be used for a prolonged duration. On top of those materials, the probe 28 can have a film to increase durability. For example, the surface of the probe 28 can be plated with a gold film. Instead of a gold-plated film, a rhodium-plated film or palladium-plated film, for example, may be formed. By forming such a film on the spring surface, the wear limit of the spring becomes higher, and the durability can be improved. Thus, the probe 28 can be used for a longer period of time. Furthermore, such a film on the probe 28 enhances adhesiveness with the conductive material 24 (such as solder) used to fix the probe 28 to the electrode section (22b-1, 22b-2), and the contact resistance is reduced. The probe 28 can be formed by any proper methods, including, for example, electrocasting.

The probe 28 may have an insulative film on its surface except the portion that comes into contact with the bump 92. The insulative film allows insulation among the probes 28 even if they touch each other.

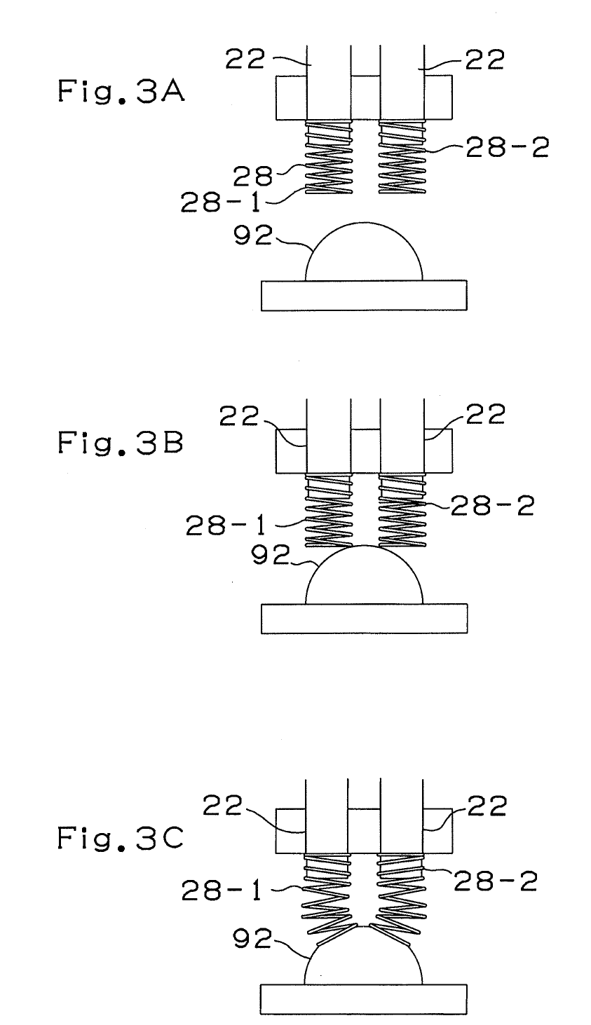

FIGS. 3A-3C illustrate how the probes (28-1, 28-2) come into contact with the substantially semicircular bump 92 of the substrate 90 under inspection. The probe (28-1) functions as a current supply probe, and the probe (28-2) as a voltage measuring probe in this embodiment. FIG. 3A shows the probes (28-1, 28-2) comprised of coil springs prior to making contact with the bump 92. FIG. 3B shows how the front ends of the probes (28-1, 28-2) come in contact with the top portion of the bump 92. FIG. 3C shows the probes (28-1, 28-2) pressed farther toward the substrate 90 than the position of the probes (28-1, 28-2) in FIG. 3B. The front end of the spring (probe (28-1, 28-2)) first comes in contact with the substantially semicircular bump 92, and then the spring is compressed, which causes the spring to warp in an outward direction along the periphery of bump 92. The front end of the probe (28-1, 28-2) is pressed against the bump 92, the force is applied in a direction to push the bump 92, and the probe (28-1, 28-2) make a secure contact with the bump 92. By using a spring as the probe (28-1, 28-2), the electrical features of a substrate having electrodes (bumps) with a small diameter (for example, about 30 to about 100 μm) can be measured precisely. A spring can easily adjust its configuration to be pressed against the bump 92, and the circular front end portion of the probe (28-1, 28-2) can easily face in the proper direction toward the bump 92. Thus, the probes (28-1, 28-2) can make a secure contact at the circular front end portion even when the bump 92 has a fine diameter. For these reasons, when the electrical features of a substrate are measured by a four-terminal method, the inspection probes are preferably made of compression springs.

### Second Embodiment

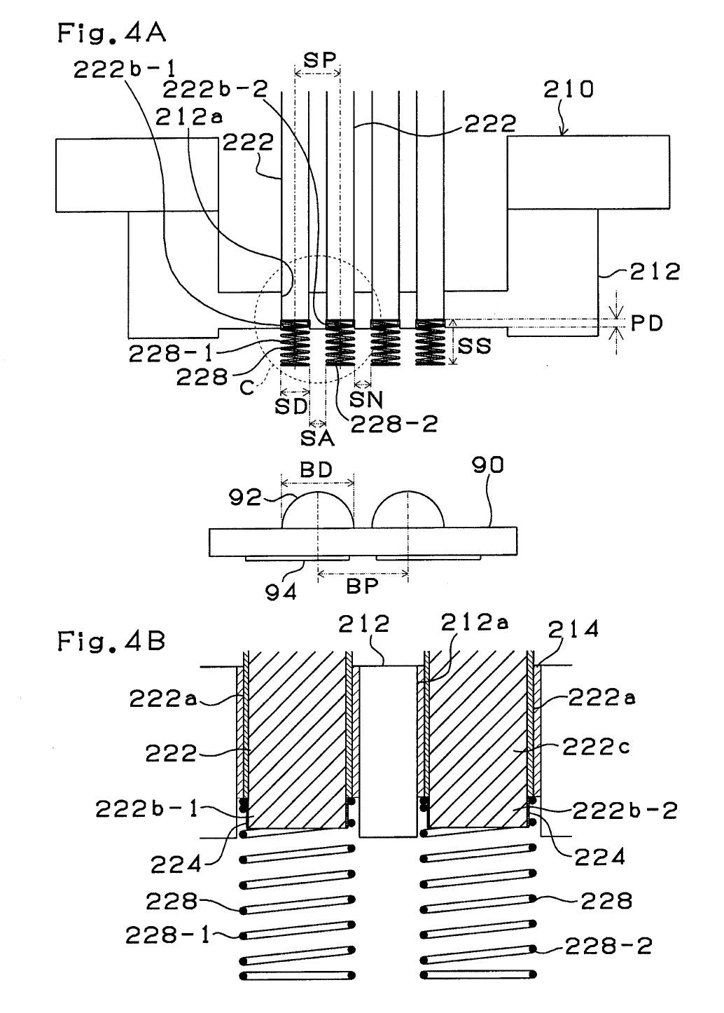

FIG. 4A is a side view of an inspection device 210 according to the Second Embodiment and a substrate 90 to be inspected. The members described in the previous embodiment are referred to by the same numbers. The inspection device 210 can be used to measure, using a four-terminal method, the electrical features of substrates to be inspected. In the illustrated embodiment, the substrate 90 has bumps (electrodes; inspection points) 92 on one surface and pads 94 on the opposite surface. The bumps 92 and the pads 94 are connected through wiring patterns (not shown) in the substrate 90. The inspection device 210 can be used to measure resistance of the wiring patterns.

The inspection device 210 includes a probe 228 and a support member 212 for holding the probe 228. The inspection device 210 is connected to an inspection system (not shown) by a connection line 222. The support member 212 has a through-hole (212a), and a part of the connection line 222 is positioned in the through-hole (212a). The connection line 222 has a conductive part exposed at an electrode section (222b-1, 222b-2) where the probe 228 is electrically connected. The electrode section (222b-1, 222b-2) does not protrude from the support member 212. The probe 228 comprises a compression spring that functions as a current supply probe (228-1) or a voltage measuring probe (228-2). A pair of a current supply probe (228-1) and a voltage measuring probe (228-2) is provided to simultaneously touch the bump 92 of the substrate 90. Unlike the First Embodiment, the rear end portion (opposite the end which touches the bump 92) of the current supply probe (228-1) and voltage measuring probe (228-2) is positioned in the through-hole (212a) of the support member 212.

The probe 228 can have a total length (SS) of, for example, about 100 μm to about 600 μm and an external diameter (SD) of, for example, about 20 μm to about 100 μm. The probes 228 can be provided at a pitch (SP) of, for example, about 30 μm to about 140 μm. The distance (SA) between the current supply probe (228-1) and voltage measuring probe (228-2) can be, for example, about 5 μm to about 30 μm. The minimum distance (SN) between the probe used for measuring one bump and the probe used for another bump next to the bump can be, for example, about 5 μm to about 40 μm. The probe 228 comprises a compression spring such as a coil spring. When the probe 228 is pressed toward the bump 92 during measurement, the probe 228 receives a load of, for example, about 0.2 gf to about 6 gf. Preferably, a load of about 0.5 gf to about 5 gf is applied. The stroke of the probe 228 can be, for example, about 50 μm to about 500 μm. The depth (PD) of the part of the probe 228 positioned in the through-hole (212a) can be, for example, about 10 μm to about 500 μm. Preferably, the depth (PD) is from about 50 μm to about 500 μm. The probe 228 can be comprised of, for example, piano wire (high carbon steel wire) with a wire diameter of about 5 μm to about 20 μm.

Substrates 90 may have bumps 92 of any suitable size. For example, bumps 92 may have a diameter (BD) of, for example, about 50 μm to about 120 μm and may be formed with a pitch (BP) of, for example, about 110 μm to about 180 μm.

FIG. 4B is a magnified cross-sectional view of the portion indicated by the circle “C” in FIG. 4A. The current supply probe (228-1) is fixed to the electrode section (222b-1) of the connection line 222, and the voltage measuring probe (228-2) is fixed to the electrode section (222b-2) of the connection line 222. The connection line 222 comprises a conductive part (222c) such as a conductive wire comprising copper, and an insulative material such as enamel film which coats the conductive part (222c). Instead of an enamel coating, a Teflon coating may be used, for example. The connection line 222 is fixed to the inner wall of the through-hole (212a) of the support member 212, using an adhesive agent 214 such as an epoxy-type adhesive agent. The diameter of the connection line 222 can be, for example, about 10 μm to about 100 μm. The external diameter of the conductive part (222c) such as copper wire can be, for example, about 5 μm to about 80 μm. The length of the connection line 222 is not particularly limited, but the total length of the connection line 222 can be, for example, about 100 mm to about 1,000 mm.

A conductive material 224 such as solder is applied on the conductive part (222c) to fix the probes (228-1, 228-2) to the electrode section (222b-1, 222b-2). Instead of solder, the electrode section (222b-1, 222b-2) and the probes (228-1, 228-2) may be fixed to each other using, for example, conductive paste or conductive adhesive paste. Also, the probe 228 may be caulked to the conductive part (222c) such as copper wire.

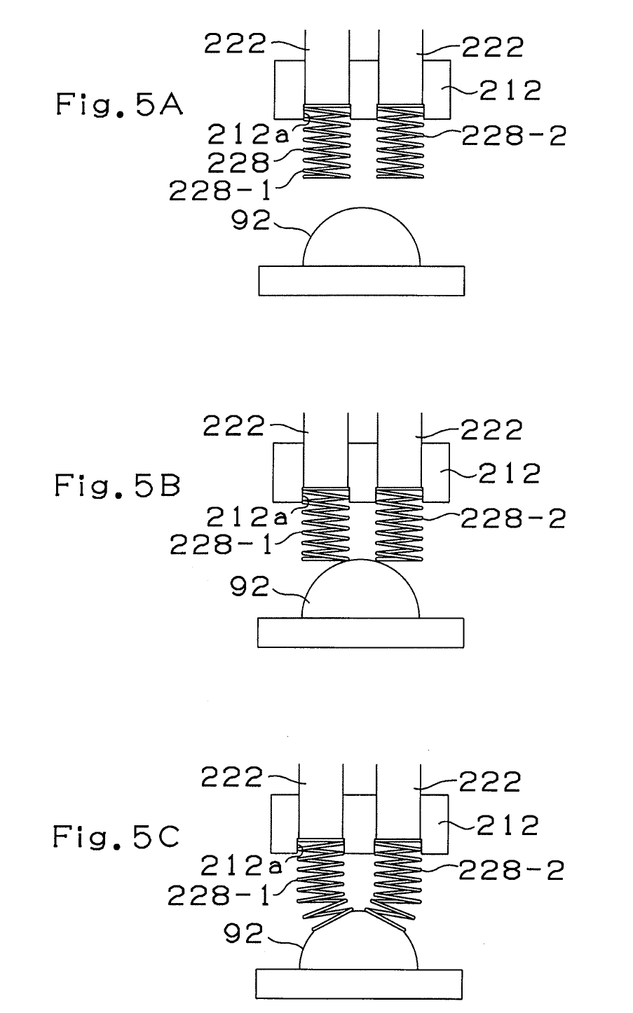

FIGS. 5A-5C illustrate how the current supply probe (228-1) and voltage measuring probe (228-2) make contact with the bump 92. FIG. 5A shows the probes (228-1, 228-2) prior to making contact with the bump 92. FIG. 5B shows how the front ends of the probes (228-1, 228-2) come in contact with the top portion of the bump 92. FIG. 5C shows the probes (228-1, 228-2) pressed farther toward the substrate 90 than the position of the probes (228-1, 228-2) in FIG. 5B. As in the First Embodiment, the probes (228-1, 228-2) comprise a compression spring, and the spring can easily adjust its configuration to be pressed against the bump 92, and thus the circular front end of the probe (228-1, 228-2) can easily face in the proper direction toward the bumps 92. When the probes (228-1, 228-2) are pressed against the bump 92 as illustrated in FIG. 5C, the probes (228-1, 228-2) make a secure contact at the circular front end portion even if the bump 92 has a fine diameter.

As shown in FIG. 5A, the rear end portion (opposite the end which touches the bump 92) of the current supply probe (228-1) and voltage measuring probe (228-2) is positioned in the through-hole (212a). Thus, when the probe (228-1, 228-2) is pressed toward the bump 92, and a part of the probe (228-1, 228-2) is warped in an outward direction along the periphery of bump 92 as in FIG. 5C, the rear-end portion of the probe (228-1, 228-2) expands inside the through-hole (212a) of the support member 212. The rear end portion of the probe (228-1, 228-2) also contracts inside the through-hole (212a) when the probe (228-1, 228-2) of FIG. 5C is brought back to the state illustrated in FIG. 5B. Accordingly, the portion of the probe (228-1, 228-2) protruding from the support member 212 can make a stroke in a more vertical direction, and thus the current supply probe (228-1) and voltage measuring probe (228-2) are less likely to get entangled. For this reason, the current supply probe (228-1) and the voltage measuring probe (228-2) do not require a large space in between to avoid becoming entangled. The current supply probe (228-1) and the voltage measuring probe (228-2) can be positioned closer to each other to simultaneously make contact with a bump having a small diameter. Thus, the inspection device 210 can properly measure, using the four-terminal method, the electrical features of a substrate having fine bumps.

Also, by having the rear end portion of the probe 228 positioned in the through-hole (212a), the portion of the probe 228 protruding from the support member 212 is shorter. As such, the probes 228 are less likely to touch each other or become entangled, and thus the risk of short circuit is reduced.

### Third Embodiment

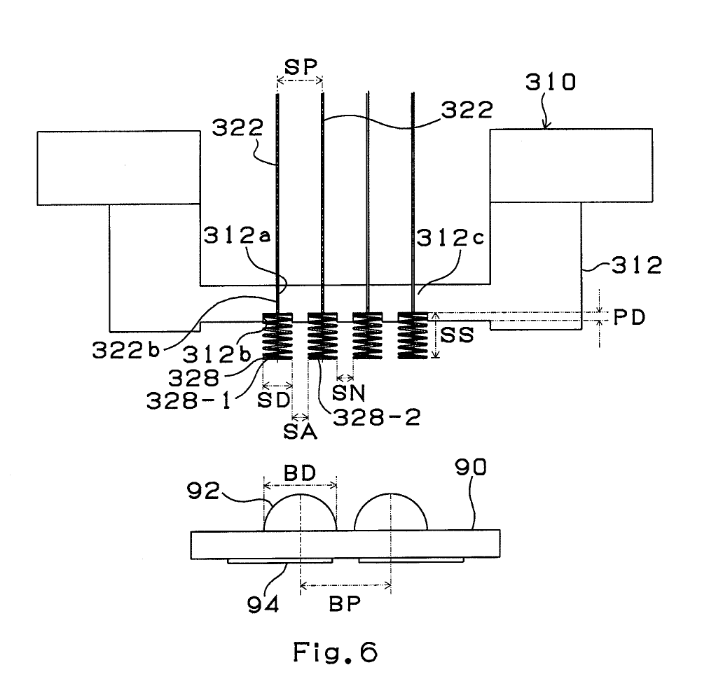

FIG. 6 is a side view of an inspection device 310 of the Third Embodiment and a substrate 90 to be inspected. The members described in the other embodiments are referred to by the same numbers. The inspection device 310 can be used to measure, using a four-terminal method, the electrical features of substrates to be inspected. In the illustrated embodiment, the substrate 90 has bumps (electrodes; inspection points) 92 on one surface and pads 94 on the opposite surface. The bumps 92 and the pads 94 are connected through wiring patterns (not shown in the drawing) in the substrate 90. The inspection device 310 can be used to measure resistance of the wiring patterns.

The inspection device 310 includes a probe 328 and a support member 312 for holding the probe 328. The inspection device 310 is connected with an inspection system (not shown) by a connection line 322. The connection line 322 connects measuring apparatus in the inspection system and an electrode section (322b). The probe 328 is used as a current supply probe (328-1) or a voltage measuring probe (328-2). The support member 312 has a through-hole (312c) comprising a first opening (312a) and a second opening (312b). The diameters are different in the first opening (312a) and the second opening (312b); the diameter of the first opening (312a) is smaller than that of the second opening (312b). The diameter of the first opening (312a) can be, for example, about 8 μm to about 30 μm, and the diameter of the second opening (312b) can be, for example, about 25 μm to about 115 μm. The electrode section (322b) is placed in the first opening (312a) and fixed to the inner wall of the first opening (312a) using an adhesive agent such as an epoxy-type adhesive agent. The rear end portion of the probe 328 is positioned in the second opening (312b).

In this embodiment, the probe 328, the electrode section (322b), and the connection line 322 comprise a single conductive body such as a wire. Thus, during measurement, an electric current is supplied to the bump 92 through the wire. The wire can be, for example, piano wire (high carbon steel wire) with a wire diameter of, for example, about 5 μm to about 20 μm. The probe 328 can be formed by, for example, configuring an end portion of the conductive body to be a compression spring (preferably, a coil spring). The electrode section (322b) can be a predetermined length (same as the depth of the first opening (312a) in the example illustrated in FIG. 6) of the conductive body extending directly from the rear end of the probe 328 (opposite the end that touches a bump 92). The connection line 322 can be a predetermined length of the wire extending directly from the rear end of the electrode section (322b) (opposite the end which is directly connected to the probe 328). As such, the electrode section (322b) is essentially an extended part of the connection line 322 in this embodiment, and this arrangement allows a direct connection between the probe 328 and the connection line 322.

The probe 328 can have a total length (SS) of, for example, about 100 μm to about 600 μm and an external diameter (SD) of, for example, about 20 μm to about 100 μm. The probes 328 can be formed at a pitch (SP) of, for example, about 30 μm to about 140 μm. The distance (SA) between the current supply probe (328-1) and voltage measuring probe (328-2) can be, for example, about 5 μm to about 30 μm. The minimum distance (SN) between the probe used for measuring one bump and the probe used for another bump next to the bump can be, for example, about 5 μm to about 40 μm. The probe 328 comprises a compression spring such as a coil spring. When the probe 328 is pressed toward the bump 92 during measurement, the probe 328 receives a load of, for example, about 0.2 gf to about 6 gf. Preferably, a load of about 0.5 gf to about 5 gf is applied. The stroke of the probe 328 can be, for example, about 50 μm to about 500 μm. The depth (PD) of the part of the probe 328 positioned in the second opening (312b), can be about 10 μm to about 500 μm. Preferably, the depth (PD) is from about 50 μm to about 300 μm. The length of the connection line 322 is not particularly limited, but the total length of the connection line 322 can be, for example, about 100 mm to about 1,000 mm.

Substrates 90 may have bumps 92 of any suitable size. For example, bumps 92 may have a diameter (BD) of, for example, about 50 μm to about 120 μm and may be formed with a pitch (BP) of, for example, about 110 μm to about 180 μm.

In this embodiment, a part of the probe 328 is positioned in the second opening (312b). Thus, similarly to the Second Embodiment, the inner wall of the second opening (312b) works to guide the probe 328 when it expands and contracts. Accordingly, the probe 328 can make a stroke in a more vertical direction, and the current supply probe (328-1) and voltage measuring probe (328-2) next to each other are less likely to get entangled. For this reason, the current supply probe (328-1) and voltage measuring probe (328-2) do not require a large space in between to avoid becoming entangled. The current supply probe (328-1) and voltage measuring probe (328-2) can be positioned closer to each other to simultaneously make contact with a bump having a small diameter. Also, in the Third Embodiment, the probe 328, the electrode section (322b) and the connection line 322 are made of a single body. Thus, the connection between the probe 328 and the electrode section (322b) and the connection between the electrode section (322b) and the connection line 322 are stronger than the connections between members made of separate bodies. The inspection device 310 therefore can measure electric properties of a substrate with high reliability.

Also, by having the rear end portion of the probe 328 positioned in the second opening (312b), the portion of the probe 328 protruding from the support member 312 is shorter. As such, the probes 328 are less likely to touch each other or become entangled, and thus the risk of short circuit is reduced.

The following examples further illustrate the invention but, of course, should not be construed as in any way limiting its scope.

### Example 1

A substrate under inspection has solder bumps formed on one surface with a pitch (BP) of 130 μm and a diameter (BD) of 70 μm. The substrate has pads on the opposite surface. The bumps and pads are connected through wiring patterns formed in the substrate. An inspection device is used to measure the resistance of the wiring patterns of the substrate. The bumps are substantially semicircular.

The inspection device has a support member and probes made of compression springs. The support member has through-holes (hole diameter of 35 μm) where connection lines are inserted. The connection line is fixed to the inner wall of the through-hole using an epoxy adhesive agent. The connection line is made of copper wire and enamel film coating the copper wire, and electrically connects the electrode section to an inspection system. The electrode section is part of the connection line where the copper wire is exposed. The electrode section protrudes from the support member and is inserted in the spring (probe) and bonded to the spring with solder. The solder is applied from outside the spring. The probes are comprised of a current supply probe and a voltage measuring probe and positioned to make simultaneous contact with the bump of the substrate.

The total length of the connection line is 500 mm long, and its diameter is 30 μm (external diameter of the copper wire: 20 μm). The spring (probe) is made of piano wire (high carbon steel wire) plated with gold film and has a diameter of 8 μm. The spring has a total length (SS) of 300 μm; a stroke of 100 μm; an external diameter (SD) of 50 μm; and a pitch (SP) of 60 μm. The distance (SA) between the current supply probe and voltage measuring probe is 10 μm. The minimum distance (SN) between the spring used for a bump and the spring for another bump next to the bump is 13 μm.

After the tips of the probes are brought into contact with the bumps, the probes are pressed toward the bumps at the spring load of 0.6 gf. The bottom parts of two probes make a secure contact with the bump by warping respectively in an outward direction along the periphery of the bump.

### Example 2

A substrate under inspection has solder bumps formed on one surface with a pitch (BP) of 123 μm and a diameter (BD) of 70 μm. The substrate has pads on the opposite surface. The bumps and pads are connected through wiring patterns formed in the substrate. An inspection device is used to measure the resistance of the wiring patterns of the substrate. The bumps are substantially semicircular.

The inspection device has a support member and probes made of compression springs. The support member has through-holes (hole diameter of 35 μm) where connection lines are inserted. The connection line is fixed to the inner wall of the through-hole using an epoxy adhesive agent. The connection line is made of copper wire (external diameter of 20 μm) and enamel film coating the copper wire. The connection line has an electrode section formed by exposing a part of the copper wire. The electrode section is inserted in the probe and fixed by using solder. The rear-end portions of the probes are positioned in the through-hole of the support member. The probes are comprised of a current supply probe and a voltage measuring probe and positioned to make simultaneous contact with the bump of the substrate.

The connection line has the total length of 500 mm and the diameter of 30 μm. The depth (PD) of the probe in the through-hole is 100 μm. The length of the probe protruding from the support member is 200 μm. The spring (probe) is made of piano wire (high carbon steel wire). The wire is plated with gold film and has a wire diameter of 8 μm. The probe has a total length (SS) of 300 μm; a stroke of 100 μm; an external diameter (SD) of 50 μm; and a pitch (SP) of 60 μm. The distance (SA) between the current supply probe and the voltage measuring probe is 10 μm. The minimum distance (SN) between the probe used for a bump and the probe for another bump next to the bump is 13 μm.

When the current supply probe and the voltage measuring probe are pressed toward the bump by applying the spring load of 0.6 gf, the two springs warp respectively in an outward direction along the periphery of the bump after touching the bump. The two springs thus makes a secure contact with fine-diameter bumps. The rear-end portion of the probe expands and contracts inside the through-hole formed in the support member. Accordingly, the springs makes a stroke in a more vertical direction. Also, because the rear-end portion of the probe is positioned in the through-hole, the protruding portion of the spring is shorter. As such, the springs do not touch each other or become entangled, and thus short circuiting is prevented.

### Example 3

A substrate under inspection has solder bumps formed on one surface with a pitch (BP) of 123 μm and a diameter (BD) of 70 μm. The substrate has pads on the opposite surface. The bumps and pads are connected through wiring patterns formed in the substrate. An inspection device is used to measure the resistance of the wiring patterns of the substrate. The bumps are substantially semicircular.

The inspection device has a support member and probes made of compression springs. The support member has through-holes each made up of a first opening (hole diameter of 20 μm) and a second opening (hole diameter of 55 μm). The inspection device is connected to an inspection system by connection lines. The connection line has an electrode section fixed to the inner wall of the first opening using an epoxy adhesive agent. The rear end portion of the probe is positioned in the second opening.

The probes are comprised of a current supply probe and a voltage measuring probe and positioned to make simultaneous contact with the bump of the substrate. The probe (spring), the electrode section, and the connection line are made of piano wire (high carbon steel wire). The probe is formed by configuring the end portion of the wire to be a coil. A part (length: 500 μm) of the wire directly extending from the spring is made to be the electrode section. A part (length: 500 mm) of the wire directly extending from the electrode section is the connection line. The piano wire has a wire diameter of 8 μm. The probe has a total length (SS) of 300 μm; a stroke of 100 μm; an outer diameter (SD) of 50 μm; and a pitch (SP) of 60 μm. The distance (SA) between the current supply probe and voltage measuring probe is 10 μm. The rear-end portion of the probe is positioned in the second opening formed in the support member, which has a vertical depth (PD) of 100 μm. The rest of the probe in the length of 200 μm protrudes from the support member.

When the current supply probe and the voltage measuring probe are pressed toward the bump by applying the spring load of 0.6 gf, the two springs warp respectively in an outward direction along the periphery of the bump after touching the bump. The rear-end portion of the probe expands and contracts in the second opening formed in the support member. Thus, the probe makes a stroke in a more vertical direction. Because the rear-end portion is accommodated in the second opening, the protruding portion of the spring is shorter. As such, the springs do not touch each other or become entangled, and thus short circuit is prevented.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A probe for inspecting a substrate, comprising:
a probe body comprising a compression spring and including a conductive material to measure an electric property of a substrate under inspection.

2. The probe of claim 1, wherein the probe body comprises a coil spring.

3. The probe of claim 1, wherein the probe body comprises a conductive part comprising a material selected from the group consisting of high carbon steel, stainless steel, beryllium copper, tungsten, and nickel.

4. The probe of claim 3, wherein the probe body comprises a film formed on the conductive part, and the film comprises a material selected from the group consisting of gold, rhodium, and palladium.

5. The probe of claim 1, wherein the compression spring has an external diameter and comprises a wire having a diameter of about 1/22 to about ¼ of the external diameter of the compression spring.

6. The probe of claim 1, wherein the compression spring has a stroke of about 50 μm to about 500 μm.

7. A device for inspecting a substrate, comprising:
a probe comprising a compression spring and including a conductive material to measure an electric property of a substrate under inspection; and
a support member configured to hold the probe.

8. The device of claim 7, wherein the support member has a through-hole to receive a connection line, and the connection line has an electrode section electrically connected to the probe.

9. The device of claim 8, wherein the probe has a front end portion and a rear end portion opposite to the front end portion, the front end portion is arranged to touch the substrate under inspection, and the rear end portion is positioned in the through-hole of the support member.

10. The device of claim 9, wherein the through-hole comprises a first opening and a second opening, the electrode section is positioned in the first opening, and the rear end portion of the probe is positioned in the second opening of the through-hole.

11. The device of claim 7, wherein the probe comprises a coil spring.

12. The device of claim 8, wherein the probe comprises a coil spring, and the electrode section is positioned in the coil spring.

13. The device of claim 8, wherein the probe and the connection line are parts of a single conductive body.

14. A method for inspecting a substrate, comprising:
providing probes that each comprise a compression spring and include a conductive material to measure an electric property of a substrate under inspection;
making a contact between the probes and an inspection point of the substrate;
supplying an electric current to the inspection point through one of the probes; and
measuring a voltage by another of the probes.

15. The method of claim 14, further comprising pressing the compression spring against the inspection point of the substrate under inspection.

16. The method of claim 15, wherein pressing the compression spring comprises compressing a coil spring while making a contact between the coil spring and the inspection point of the substrate.

17. The method of claim 16, wherein making a contact comprises making a contact between a circular end portion of the coil spring and a surface of an electrode having a substantially semicircular shape and being positioned at the inspection point of the substrate.

18. The method of claim 17, wherein making a contact comprises making a contact at the circular end portion of the coil spring having a diameter of about ½ to about ¼ of a diameter of the electrode positioned at the inspection point of the substrate.
